(19) United States
(12) Patent Application Publication
(10) Pub. No.: US 2016/0149073 A1
(43) Pub. Date: May 26, 2016

(54) Light-Emitting Diode Fabrication Method

(71) Applicant: TIANJIN SANAN OPTOELECTRONICS CO., LTD., Tianjin (CN)

(72) Inventors: LI-MING SHU, Tianjin (CN); DONG-YAN ZHANG, Tianjin (CN); XIAO-FENG LIU, Tianjin (CN); ZHI-BIN LIU, Tianjin (CN); LIANG-JUN WANG, Tianjin (CN); DU-XIANG WANG, Tianjin (CN)

(73) Assignee: TIANJIN SANAN OPTOELECTRONICS CO., LTD., Tianjin (CN)

(21) Appl. No.: 14/750,145

(22) Filed: Jun. 25, 2015

(30) Foreign Application Priority Data
Nov. 25, 2014 (CN) 201410684601.9

(51) Int. Cl. H01L 33/06; H01L 33/24; H01L 33/14; H01L 33/00; H01L 33/32

(52) U.S. Cl. CPC H01L 33/06; H01L 33/0075; H01L 33/32; H01L 33/145; H01L 33/24

(57) ABSTRACT

A method of fabricating a light-emitting diode includes: proving a substrate; forming an N-type layer, a low-temperature AlₓIn_{y}Ga_{1-x-y}N (0≦x≦1, 0≦y≦1, x and y cannot both be zero at the same time) layer, a multiple quantum-well active region, an Al_{z}Ga_{1-z}N (0≦z≦1) electron blocking layer, an AlₓIn_{y}Ga_{1-x-y}N (0≦x≦1, 0≦y≦1) separation layer and a P-type layer over the substrate in successive; before growth of the multiple quantum-well active region, growing a low-temperature AlₓIn_{y}Ga_{1-x-y}N layer to form a “V”-shaped indentation or pit; after growth of the multiple quantum-well active region, growing a thin Al_{z}Ga_{1-z}N electron blocking layer and then a separation layer under two-dimensional growth mode to form holes between the active region and the P-type layer to separate throughout dislocation within the V pit coverage range and contact with the P-type layer, thus eliminating current leakage and improving inverse current leakage capacity and anti-static capacity of the epitaxial wafer.

### CROSS-REFERENCE TO RELATED APPLICATIONS

The present application is a continuation of and claims priority to Chinese Patent Application No. CN 201410684601.9 filed on Nov. 25, 2014, the disclosure of which is hereby incorporated by reference in its entirety.

### BACKGROUND

Light-emitting diode (LED) is a semiconductor light-emitting device, taking semiconductor P-N junction as the light-emitting structure. Currently, gallium nitride (GaN) is regarded as the third-generation semiconductor material and the GaN-based light-emitting diode with InGaN/GaN active region is taken as the most potential light-emitting source.

In the epitaxial wafer structure of conventional GaN-based light-emitting diode, the dislocation throughout the entire P-N junction is one of the main reasons that results in performance reduction of light-emitting diode, which causes lower internal quantum efficiency, inverse current leakage and poor anti-electrostatic breakdown capacity. Reliability of chip becomes even more important as the demand for large-size chip gets higher. Therefore, it is necessary to provide an epitaxial wafer structure of light-emitting diode with simple fabrication, effective reduction of throughout dislocation and improved light-emitting efficiency.

### SUMMARY

The present disclosure provides a fabrication method of light-emitting diode, and the main technical scheme is that: 1) take heat treatment for the substrate with hydrogen or with mixed gas of hydrogen, nitrogen and ammonia gas; 2) grow a low-temperature AlₓGa₁₋ₓN (0≦x≦1) buffer layer, an undoped GaN layer, an N-type layer, a low-temperature AlₓIn_{y}Ga_{1-x-y}N (0≦x≦1, 0≦y≦1, x and y cannot both be zero at the same time) layer, a multiple quantum-well active region, an Al_{z}Ga_{1-z}N (0≦z≦1) electron blocking layer, a separation layer and a P-type layer over the substrate after heat treatment; and 3) the low-temperature AlₓIn_{y}Ga_{1-x-y}N layer and the multiple quantum-well active region form a V pit, with the thin Al_{z}Ga_{1-z}N (0≦z≦1) electron blocking layer embedded but not filled up the V pit, and gas holes are formed through the separation layer formed after two-dimensional growth.

Further, the low-temperature AlₓIn_{y}Ga_{1-x-y}N layer is a body structure or a superlattice structure with thickness of 1-1000 nm. The In components and Al components at different positions of this layer keep stable or appear linear increase or decrease, or in zigzag, rectangle, Gaussian distribution or stair-step distribution.

Further, the Al_{z}Ga_{1-z}N electron blocking layer is a body structure or a superlattice structure with thickness of 0.1-200 nm, The Al components at different positions of this layer keep stable or appear linear increase or decrease, or in zigzag, rectangle, Gaussian distribution or stair-step distribution.

Further, the Al_{z}Ga_{1-z}N electron blocking layer is embedded in but not filled up the entire V pit.

Further, after growth of the Al_{z}Ga_{1-z}N electron blocking layer, grow an AlₓIn_{y}Ga_{1-x-y}N (0≦x≦1, 0≦y≦1) separation layer from two-dimensional growth. The In components and Al components at different positions of this layer keep stable or appear in zigzag, rectangle, Gaussian distribution or stair-step distribution.

Further, during growth of the separation layer, a two-dimensional growth environment is formed through low pressure, high temperature and high rotation rate, i.e., the reaction chamber is set as 100-300 torr, 600-1200° C. and 800-1200 rpm and the growth thickness is 0.1-200 nm.

Further, the separation layer from two-dimensional growth is undoped or Mg-doped, with doping concentration keeping stable or appearing linear increase or decrease, or in zigzag, rectangle, Gaussian distribution or stair-step distribution.

Further, the P-type layer is a GaN layer or an In_{y}Ga_{1-y}N layer.

A fabrication of the epitaxial wafer structure of light-emitting diode is provided. Before growth of the multiple quantum-well active region, grow a low-temperature AlₓIn_{y}Ga_{1-x-y}N (0≦x≦1, 0≦y≦1, x and y cannot both be zero at the same time) layer. Under low temperature condition, form a V pit with lattice mismatch between the ternary or quaternary compound and GaN material. Growth rate of the III-IV-group compound at the V pit side is lower than that at the vertical lattice plane of the substrate. As the V pit in the multiple quantum-well active region grows larger, the thin electron blocking layer is embedded in but not filled up the entire V pit. Provide favorable environment for two-dimensional growth under low pressure, high temperature and high rotation rate to make lateral growth rate larger than vertical growth rate. Grow a separation layer to combine the V pit. Form holes between the active region and the separation layer to separate throughout dislocation within the V pit coverage range and contact with the separation layer, thus eliminating current leakage and improving inverse current leakage capacity and anti-static capacity of the epitaxial wafer.

This present disclosure is highly operable and has high commercial value since growth mode is available by conventional epitaxial film growth equipment like MOCVD, and the purpose of present disclosure is achieved only by changing structure of epitaxial layer and different growth modes of epitaxial layer.

### BRIEF DESCRIPTION OF THE DRAWINGS

FIG. 1 is a schematic diagram of the epitaxial wafer structure of light-emitting diode according to present disclosure.

In the drawings: 1: substrate; 2: low-temperature AlₓGa₁₋ₓN buffer layer (0≦x≦1); 3: undoped GaN layer; 4: N-type GaN layer; 5: low-temperature AlₓIn_{y}Ga_{1-x-y}N (0≦x≦1, 0≦y≦1) layer; 6: multiple quantum-well active region; 7: Al_{z}Ga_{1-z}N electron blocking layer (0≦z≦1); 8 separation layer of two-dimensional growth mode; 9: P-type layer; A: holes, B: throughout dislocation in the formed V pit, C: throughout dislocation blocked by air holes extending to the P-type layer, D: throughout dislocation extending to the P-type layer.

### DETAILED DESCRIPTION

### Embodiment 1

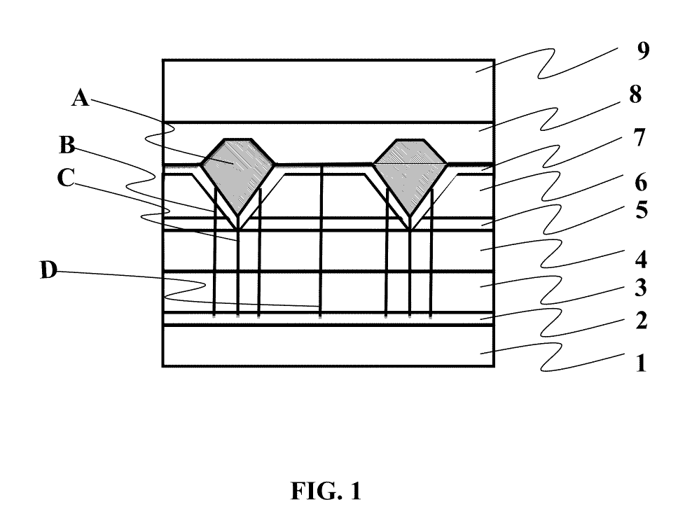

FIG. 1 is a schematic diagram of the epitaxial wafer structure of light-emitting diode. Fabrication process of this embodiment comprises, from bottom to up: (1) a sapphire C-side substrate 1; (2) a low-temperature AlₓGa₁₋ₓN buffer layer 2 made of GaN, MN, AlGaN or their combination with film thickness of 10-100 nm; (3) an undoped GaN layer 3 with film thickness of 300-7000 nm, preferably 3500 nm; (4) an N-type GaN layer 4, in which, the doping source is silicane and doping concentration is 1×10¹⁸-2×10¹⁹ cm⁻³, preferably 1.2×10¹⁹ cm⁻³; (5) a low-temperature AlₓIn_{y}Ga_{1-x-y}N (0≦x≦1, 0≦y≦1, x and y cannot both be zero at the same time) layer 5, with growth temperature of 600-1200° C., preferably 750° C., and film thickness of 500-1000 nm; (6) a multiple quantum-well active region 6, with InGaN as the well layer and GaN or AlGaN or their combination as the cladding layer, in which, the cladding layer is about 50-150 nm thick and the well layer is about 1-20 nm thick and a plurality of cycle structures are formed; (7) an Al_{z}Ga_{1-z}N electron blocking layer 7 with film thickness of 0.1-200 nm; (8) a 0.1-200 nm separation layer 8 made of undoped AlₓIn_{y}Ga_{1-x-y}N or P-type doping AlₓIn_{y}Ga_{1-x-y}N (0≦x≦1, 0≦y≦1) of two-dimensional growth mode, preferably AlₓGa₁₋ₓN structure and thickness of 50 nm; (9) a P-type layer 9, which, specifically, can be a P-type GaN layer or P-type In_{y}Ga_{1-y}N layer, preferably P-type GaN layer with film thickness of 20 nm-2000 nm, and preferably 200 nm.

During growth of the low-temperature AlₓIn_{y}Ga_{1-x-y}N layer 5, a V pit is formed through lattice mismatch between the ternary or quaternary compound and the GaN material, in which, the V pit side is a (1-101) surface; preferably, 750° C. is adopted to form a 50-150 nm V pit after growth of the active region and the electron blocking layer, which is easy for separation layer combination and generation of holes.

During growth of the multiple quantum-well active region 6, growth rate at the C side is larger than that at the inner side of the V pit, and the V pit grows larger with growth of the active region.

During growth of the Al_{z}Ga_{1-z}N electron blocking layer 7, the Al_{z}Ga_{1-z}N electron blocking layer is embedded in but not filled up the entire V pit.

During growth of the separation layer from two-dimensional growth, a two-dimensional growth is formed through low pressure, high temperature and high rotation rate, i.e., the reaction chamber is set as 100-300 torr, 600-1200° C. and 800-1200 rpm. Grow a separation layer of two-dimensional growth mode. The V pit is combined as lateral growth rate is larger than vertical growth rate under the two-dimensional growth and holes are formed between the active region and the P-type layer.

In this embodiment, before growth of the multiple quantum-well active region, a low-temperature AlₓIn_{y}Ga_{1-x-y}N layer is grown and a V pit is formed. After growth of the multiple quantum-well active region, grow a thin Al_{z}Ga_{1-z}N electron blocking layer and then a separation layer of two-dimensional growth mode to form holes between the active region and the separation layer to separate throughout dislocation within the V pit coverage range and contact with the separation layer, thus eliminating current leakage and improving inverse current leakage capacity and anti-static capacity of the epitaxial wafer.

As a first alternating embodiment of this embodiment, during growth of the low- temperature AlₓIn_{y}Ga_{1-x-y}N layer, the In components of this layer and In component contents at different positions of this layer are controlled to control the V pit size and density, thus effectively controlling size and density of the holes after growth of the multiple quantum-well active region and good for complete combination of the V pit during growth of the two-dimensional separation layer.

As a second alternating embodiment of this embodiment, during growth of the Al_{z}Ga_{1-z}N electron blocking layer, the Al components at different positions of this layer are controlled to make the Al component at minimum low before gradual increase, thus greatly improving electron blocking capacity and reducing growth thickness of the Al_{z}Ga_{1-z}N electron blocking layer.

As a third alternative embodiment of this embodiment, during growth of the separation layer of two-dimensional growth mode, Mg is input to reach concentration of 1×10¹⁶-2×10²⁰cm⁻³; a Mg-doped separation layer is used to replace the P-type layer to increase injection capacity and efficiency of holes.

### Embodiment 2

Different from Embodiment 1, in this embodiment, the low-temperature AlₓIn_{y}Ga_{1-x-y}N layer (0≦x≦1, 0≦y≦1, x and y cannot both be zero at the same time) and the Al_{z}Ga_{1-z}N electron blocking layer are grown under AlₓIn_{y}Ga_{1-x-y}N/GaN and Al_{z}Ga_{1-z}N/GaN superlattice mode respectively with 1-100 cycles to ensure a better growth quality of the low-temperature AlₓIn_{y}Ga_{1-x-y}N layer and the Al_{z}Ga_{1-z}N electron blocking layer during growth; in particular, during growth of the Al_{z}Ga_{1-z}N electron blocking layer, a higher Al component is obtained to increase barrier height of the electron blocking layer and improve electron blocking capacity.

As a first alternating embodiment of this embodiment, during growth of the low-temperature AlₓIn_{y}Ga_{1-x-y}N layer, the In components and Al components or thicknesses at different positions of this layer appear linear increase or decrease, or in zigzag, rectangle, Gaussian distribution or stair-step distribution to form a large-size V pit under high temperature conditions and improve material quality of the epitaxial wafer

As a second alternative embodiment of this embodiment, during growth of the Al_{z}Ga_{1-z}N electron blocking layer, the Al components or thicknesses at different positions of this layer appear linear increase or decrease, or in zigzag, rectangle, Gaussian distribution or stair-step distribution to improve electron blocking capacity of the Al_{z}Ga_{1-z}N layer.

### Embodiment 3

Different from Embodiment 1 and Embodiment 2, in this embodiment, quaternary compound AlₓIn_{y}Ga_{1-x-y}N (0≦x≦1, 0≦y≦1) is used to replace the Al_{z}Ga_{1-z}N electron blocking layer. Since it is easy to adjust lattice size of the quaternary compound, a better lattice match can be formed with the multiple quantum-well active region to improve quality of the epitaxial wafer.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A method of fabricating a light-emitting diode (LED), comprising:
providing a substrate;
growing over the substrate sequentially an N-type layer, a low-temperature AlₓIn_{y}Ga_{1-x-y}N (0≦x≦1, 0≦y≦1, wherein x and y are not both be zero at the same time) layer, a multiple quantum-well active region, an Al_{z}Ga_{1-z}N (0≦z≦1) electron blocking layer, and an AlₓIn_{y}Ga_{1-x-y}N (0≦x≦1, 0≦y≦1) separation layer;
wherein the low-temperature AlₓIn_{y}Ga_{1-x-y}N layer and the multiple quantum-well active region form a “V”-shaped indentation, and the Al_{z}Ga_{1-z}N electron blocking layer grown latter is embedded in but not filled up the “V”-shaped indentaion;
growing a separation layer in a two-dimensional growth mode to form holes between the multiple quantum-well active region and the separation layer to obtain an epitaxial wafer of the LED.

2. The method of claim 1, wherein the “V”-shaped indentation is formed through lattice mismatch between the AlₓIn_{y}Ga_{1-x-y}N (0≦x≦1, 0≦y≦1, wherein x and y are not both be zero at the same time) layer and the N-type layer material under a low temperature.

3. The method of claim 1, wherein a buffer layer is grown over the substrate, and an N-type layer is formed after growth of an undoped GaN layer.

4. The method of claim 1, wherein the low-temperature AlₓIn_{y}Ga_{1-x-y}N (0≦x≦1, 0≦y≦1, wherein x and y are not both be zero at the same time) layer is a bulk structure or a superlattice structure.

5. The method of claim 1, wherein a growth temperature of the low-temperature AlₓIn_{y}Ga_{1-x-y}N (0≦x≦1, 0≦y≦1, wherein x and y are not both be zero at the same time) layer is at 600-1000° C., and In components and Al components at different positions of the low-temperature AlₓIn_{y}Ga_{1-x-y}N layer are constant or have a linear increase or decrease.

6. The method of claim 1, wherein the Al_{z}Ga_{1-z}N (0≦z≦1) electron blocking layer is about 0.1-200 nm thick, and has a bulk structure or a superlattice structure.

7. The method of claim 1, wherein during growth of the separation layer, a reaction chamber is set at 100-300 torr, 600-1200° C. and 800-1200 rpm, and a AlₓIn_{y}Ga_{1-x-y}N (0≦x≦1, 0≦y≦1) separation layer is formed under a two-dimensional growth environment with a low pressure, a high temperature, and a high rotation rate.

8. The method of claim 1, wherein the separation layer from the two-dimensional growth mode is undoped or P-type doped.

9. The method of claim 1, wherein Al components and In components at different positions of the separation layer from the two-dimensional growth mode have a linear increase or decrease, a zigzag shaped distribution, a rectangle shaped distribution, a Gaussian distribution, or a stair-step distribution

10. The method of claim 1, wherein a P-type layer is grown over the separation layer from the two-dimensional growth mode.

11. A light-emitting diode (LED), comprising:
a substrate;
sequentially grown over the substrate, an N-type layer, a low-temperature AlₓIn_{y}Ga_{1-x-y}N (0≦x≦1, 0≦y≦1, wherein x and y are not both be zero at the same time) layer, a multiple quantum-well active region, an Al_{z}Ga_{1-z}N (0≦z≦1) electron blocking layer, and an AlₓIn_{y}Ga_{1-x-y}N (0≦x≦1, 0≦y≦1) separation layer;
wherein the low-temperature AlₓIn_{y}Ga_{1-x-y}N layer and the multiple quantum-well active region form a “V”-shaped indentation, and the Al_{z}Ga_{1-z}N electron blocking layer grown latter is embedded in but not filled up the “V”-shaped indentation;
a separation layer from a two-dimensional growth mode forming holes between the multiple quantum-well active region and the separation layer to obtain an epitaxial wafer of the LED.

12. The LED of claim 11, wherein the “V”-shaped indentation is formed through lattice mismatch between the AlₓIn_{y}Ga_{1-x-y}N (0≦x≦1, 0≦y≦1, wherein x and y are not both be zero at the same time) layer and the N-type layer material under a low temperature.

13. The LED of claim 11, wherein a buffer layer is grown over the substrate, and an N-type layer is formed after growth of an undoped GaN layer.

14. The LED of claim 11, wherein the low-temperature AlₓIn_{y}Ga_{1-x-y}N (0≦x≦1, 0≦y≦1, wherein x and y are not both be zero at the same time) layer is a bulk structure or a superlattice structure.

15. The LED of claim 11, wherein a growth temperature of the low-temperature AlₓIn_{y}Ga_{1-x-y}N (0≦x≦1, 0≦y≦1, wherein x and y are not both be zero at the same time) layer is at 600-1000° C., and In components and Al components at different positions of the low-temperature AlₓIn_{y}Ga_{1-x-y}N layer are constant or have a linear increase or decrease.

16. The LED of claim 11, wherein the Al_{z}Ga_{1-z}N (0≦z≦1) electron blocking layer is about 0.1-200 nm thick, and has a bulk structure or a superlattice structure.

17. The LED of claim 11, wherein during growth of the separation layer, a reaction chamber is set at 100-300 torr, 600-1200° C. and 800-1200 rpm, and a AlₓIn_{y}Ga_{1-x-y}N (0≦x≦1, 0≦y≦1) separation layer is formed under a two-dimensional growth environment with a low pressure, a high temperature, and a high rotation rate.

18. The LED of claim 11, wherein the separation layer from the two-dimensional growth mode is undoped or P-type doped.

19. The LED of claim 11, wherein Al components and In components at different positions of the separation layer from the two-dimensional growth mode have a linear increase or decrease, a zigzag shaped distribution, a rectangle shaped distribution, a Gaussian distribution, or a stair-step distribution

20. The LED of claim 11, wherein a P-type layer is grown over the separation layer from the two-dimensional growth mode.
